(19) United States
(12) Patent Application Publication
(10) Pub. No.: US 2011/0049643 A1
(43) Pub. Date: Mar. 3, 2011

(54) SEMICONDUCTOR DEVICE AND METHOD OF MANUFACTURING THE SAME

(76) Inventor: Misa MATSUOKA, Yokohama-shi (JP)

(21) Appl. No.: 12/871,462

(22) Filed: Aug. 30, 2010

(30) Foreign Application Priority Data
Sep. 1, 2009 (JP) 2009-201968

(51) Int. Cl. H01L 29/78; H01L 21/336; H01L 21/8238

(52) U.S. Cl. 257/408; 438/285; 438/231; 257/E21.437; 257/E21.632; 257/E29.266

(57) ABSTRACT

According to one embodiment, a method of manufacturing a semiconductor device including forming a gate structure includes a metal gate electrode on a semiconductor substrate, forming two first sidewalls of an insulating material on both side surfaces of the gate structure, introducing impurity into the semiconductor substrate using the first sidewalls as a mask, and forming two extension regions of a first conductivity type and two halo regions of a second conductivity type deeper than the extension regions in the semiconductor substrate, forming two recess regions on the semiconductor substrate by etching the semiconductor substrate using the first sidewalls as a mask, forming SiGe layers in the recess regions, forming two second sidewalls of an insulating material on side surfaces of the first sidewalls, and dry etching the mask layer.

### CROSS-REFERENCE TO RELATED APPLICATIONS

This application is based upon and claims the benefit of priority from Japanese Patent Application No. 2009-201968, filed Sep. 1, 2009; the entire contents of which are incorporated herein by reference.

### FIELD

Embodiments described herein relate generally to a semiconductor device and a method of manufacturing the same.

### BACKGROUND

With the integration and speed of semiconductor devices ever on the increase due to technical progress, the micronization of the metal oxide semiconductor field-effect transistor (MOSFET) is advancing. As a part of this progress, a technique is known in which a film of a high dielectric constant (high-k film) is used as a gate insulating film to decrease the thickness of the gate insulating film without increasing a gate leakage current on the one hand and a metal gate is used for a gate electrode to prevent the capacitance reduction caused by the depletion of the gate electrode on the other hand. A technique is also known in which silicon in a channel region is deformed by embedding silicon germanium (SiGe) in a silicon substrate thereby to improve the mobility of the MOSFET.

The process integration that can realize these techniques at the same time has yet to be developed. A method of manufacturing the MOSFET using the metal gate and the embedded SiGe (eSiGe) is described below by way of a example.

1. A laminated gate including the metal gate is formed and processed using a hard mask.

2. A sidewall for eSiGe is formed.

3. A silicon substrate is recessed using lithography.

4. An eSiGe film is formed in the recess region.

5. The hard mask is removed by wet etching.

6. A sidewall for a halo/extension region is formed and ions for the halo/extension region are implanted.

7. Ions for a source/drain region are implanted. 8. Heat treatment is conducted to activate impurities.

The manufacture of the MOSFET through these processes poses the problems described below.

(Problem 1) In the process of manufacturing the MOSFET comprising a metal gate, the metal gate is required to be covered in its entirety by a protective film for delivery to prevent the metal contamination of the device. In removing the hard mask by wet etching in the process 5 described above, however, the sidewall covering the metal gate may be etched off and the metal gate may be exposed.

(Problem 2) Ions for the halo/extension region are implanted after forming eSiGe, and therefore, the height of the embedded SiGe determines the amount by which the extension region is overlapped. The eSiGe film has a large wafer in-plane dependency and pattern dependency, and therefore, the variation thereof causes the variation of the MOSFET characteristics. As a result, the eSiGe film cannot be formed at a higher level than the gate.

(Problem 3) Ions for the halo region and the source/drain region are implanted in the SiGe embedded in the recess region, and therefore, a defect may be induced in eSiGe with the stress released.

As a technique related to this field, a semiconductor device comprising a metal gate is disclosed (see Jpn. Pat. Appln. KOKAI Publication No. 2008-172209).

### BRIEF DESCRIPTION OF THE DRAWINGS

FIG. 1 is a sectional view showing the process of manufacturing a semiconductor device according to a first embodiment;

FIG. 2 is a sectional view showing the process of manufacturing a semiconductor device continued from FIG. 1;

FIG. 3 is a sectional view showing the process of manufacturing a semiconductor device continued from FIG. 2;

FIG. 4 is a sectional view showing the process of manufacturing a semiconductor device continued from FIG. 3;

FIG. 5 is a diagram showing an example of a recess region 26;

FIG. 6 is a sectional view showing the process of manufacturing a semiconductor device continued from FIG. 4;

FIG. 7 is a sectional view showing the process of manufacturing a semiconductor device continued from FIG. 6;

FIG. 8 is a sectional view showing the process of manufacturing a semiconductor device continued from FIG. 7;

FIG. 9 is a sectional view showing the process of manufacturing a semiconductor device continued from FIG. 8;

FIG. 10 is a sectional view showing the process of manufacturing a semiconductor device continued from FIG. 9;

FIG. 11 is a sectional view of another configuration of the semiconductor device according to the first embodiment;

FIG. 12 is a sectional view showing a first example of the structure of the conventional pMOSFET;

FIG. 13 is a sectional view showing a second example of the structure of the conventional pMOSFET;

FIG. 14 is a sectional view showing a third example of the structure of the conventional pMOSFET;

FIG. 15 is a sectional view showing the pMOSFET extracted according to the first embodiment;

FIG. 16 is a sectional view showing the process of manufacturing a semiconductor device according to a second embodiment;

FIG. 17 is a sectional view showing the process of manufacturing a semiconductor device continued from FIG. 16;

FIG. 18 is a sectional view showing the process of manufacturing a semiconductor device continued from FIG. 17;

FIG. 19 is a sectional view showing the process of manufacturing a semiconductor device continued from FIG. 18;

FIG. 20 is a sectional view showing the process of manufacturing a semiconductor device continued from FIG. 19;

FIG. 21 is a sectional view showing the process of manufacturing a semiconductor device continued from FIG. 20;

FIG. 22 is a sectional view showing the process of manufacturing a semiconductor device continued from FIG. 21;

FIG. 23 is a sectional view showing the process of manufacturing a semiconductor device continued from FIG. 22;

FIG. 24 is a sectional view showing the process of manufacturing a semiconductor device continued from FIG. 23; and

FIG. 25 is a sectional view of another configuration of the semiconductor device according to the second embodiment.

### DETAILED DESCRIPTION

In general, according to one embodiment, there is provided a method of manufacturing a semiconductor device, the method comprising:

depositing a laminate film comprising a material of a gate insulating film and a material of a metal gate electrode on a semiconductor substrate;

forming a mask layer on the laminate film;

processing the laminate film using the mask layer as a mask, and forming a gate structure comprising the gate insulating film and the metal gate electrode on the semiconductor substrate;

forming two first sidewalls of an insulating material on both side surfaces of the gate structure;

introducing impurity into the semiconductor substrate using the first sidewalls as a mask, and forming two extension regions of a first conductivity type and two halo regions of a second conductivity type deeper than the extension regions in the semiconductor substrate;

forming two recess regions on the semiconductor substrate by etching the semiconductor substrate using the first sidewalls as a mask;

forming SiGe layers in the recess regions;

forming two second sidewalls of an insulating material on side surfaces of the first sidewalls; and

dry etching the mask layer.

The embodiments will be described hereinafter with reference to the accompanying drawings. In the description which follows, the same or functionally equivalent elements are denoted by the same reference numerals, to thereby simplify the description.

### First Embodiment

An example of the method of manufacturing a semiconductor device (MOSFET) according to a first embodiment is explained with reference to the drawings.

A semiconductor substrate 11 is formed with an n-type well (nwell) 12 and a p-type well (pwell) 13, and an element-isolation insulating layer 14, which isolates the n-type well 12 and the p-type well 13 electrically, is formed between the two wells. The n-type well 12 is formed with a p-channel MOSFET (pMOSFET) while the p-type well 13 is formed with an re-channel MOSFET (nMOSFET). A silicon substrate, for example, is used as the semiconductor substrate 11.

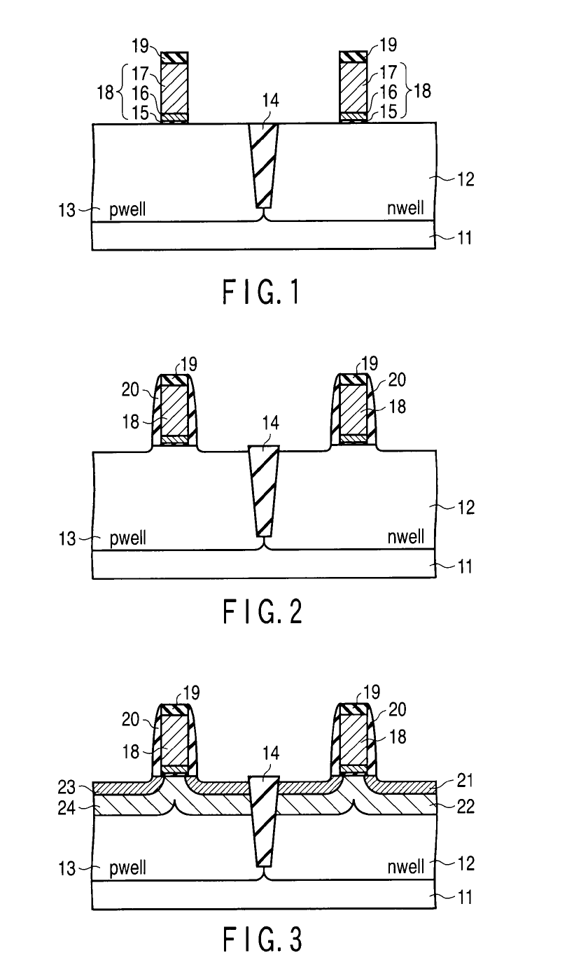

As shown in FIG. 1, the material of a gate insulating film 15, the material of a metal gate electrode 16 and the material of a polysilicon gate electrode 17 are formed in this order on the n-type well 12 and the p-type well 13. A high-dielectric-constant film (high-k film) is used for the gate insulating film 15. A metal such as tungsten (W) or titanium (Ti) is used for the metal gate electrode 16.

A hard mask 19 of a silicon nitride (SiN), for example, is formed by lithography on the polysilicon gate electrode 17. Using this hard mask 19 as a mask, a laminated gate film is processed. As a result, a laminated gate structure 18 including the gate insulating film 15, the metal gate electrode 16 and the polysilicon gate electrode 17 is formed on each of the n-type well 12 and the p-type well 13.

As shown in FIG. 2, a sidewall 20 of a silicon nitride (SiN), for example, is formed on each side surface of the laminated gate structure 18 to achieve dual purpose as a protective film of the metal gate and a sidewall for ion implantation to form a halo region and an extension region.

As shown in FIG. 3, ions are implanted in the n-type well 12, so that two halo regions 22 and two extension regions 21 are formed in the n-type well 12. The halo regions 22 for the pMOSFET are provided for suppression of the short channel effect, and have the same conductivity, i.e., n type, as the n-type well 12 with the impurity concentration higher than that of the n-type well 12. The extension regions 21 for the pMOSFET are formed to relax the channel field, and have the same conductivity, i.e., p type, as the source-drain region with the impurity concentration lower than that of the source/drain region.

Similarly, two halo regions 24 and two extension regions 23 are formed in the p-type well 13 by ion implantation in the p-type well 13. The halo regions 24 of the nMOSFET have the same conductivity, i.e., p type, as the p-type well 13, and the extension regions 23 have the same conductivity, i.e., n type, as the source/drain region. After that, in order to activate the impurity implantation region, heat treatment is conducted possibly using spike rapid thermal annealing (RTA), laser spike annealing (LSA) or dynamic surface annealing (DSA). This heat treatment determines the overlap amount of the extension region and the laminated gate structure 18. After that, an epitaxial film of a silicon nitride, for example, may be formed as a protective film on the well.

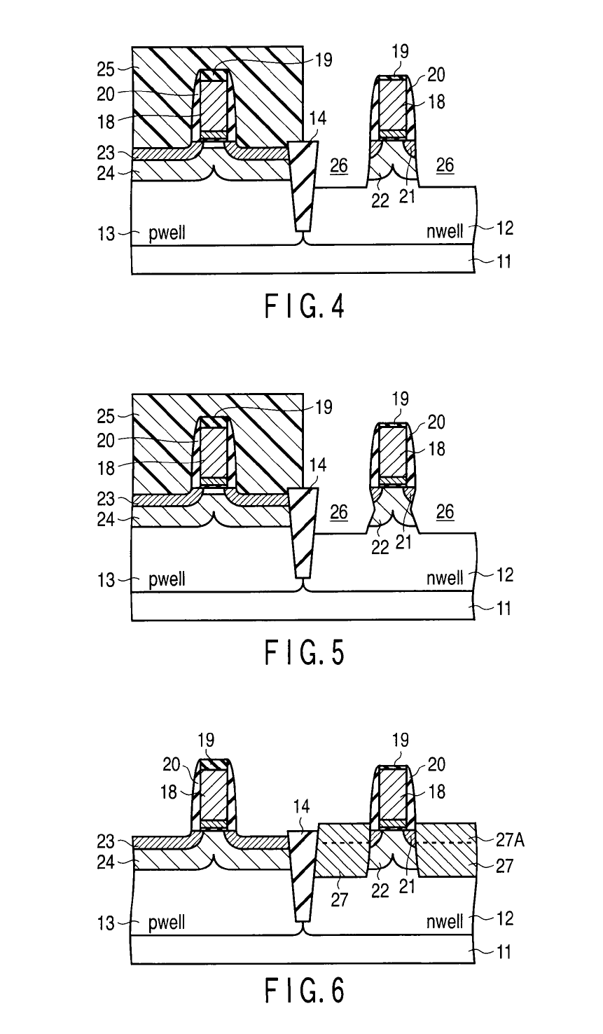

As shown in FIG. 4, a resist 25 is formed by lithography to cover the region other than the one where a silicon germanium (SiGe) layer for the pMOSFET is to be formed. Then, the semiconductor substrate 11 (specifically, the n-type well 12) is etched thereby to from recess regions 26 in the n-type well 12. The recess regions 26 are at least deeper than the halo regions 22. The recess form may be anisotropic as shown in FIG. 4, or in the shape of Σ (sigma) with the side surface of the recess region 26 depressed toward the semiconductor substrate 11 as shown in FIG. 5.

After that, as shown in FIG. 6, a cleaning process (epitaxial pre-process) is executed to remove a natural oxide film from the surface of the semiconductor substrate 11, after which SiGe layers 27 are formed in the recess regions 26. In the process, the SiGe layers 27 are formed to a greater thickness to compensate for the amount by which the substrate is etched in processing the sidewalls for the source/drain region. In FIG. 6, the upper surface of the SiGe layers 27 are higher than the upper surface of the semiconductor substrate 11 directly under the laminated gate structure 18. The lattice constant of SiGe, or specifically, germanium (Ge) is larger than that of silicon (Si). Once the SiGe layer is embedded in the silicon layer, therefore, the compression stress is applied to the channel region held with the SiGe layer, often causing the distortion of the channel region. This compression stress improves the mobility of holes, and therefore, the operation of the pMOSFET can be performed at higher speed. As described above, in the case where the recess regions 26 are in the shape of Σ (sigma), SiGe intrudes into the depression of the recess region 26 and the compression stress on the channel region can be increased.

The SiGe layers 27 may be formed using the in situ boron doping process or the non-doped SiGe not doped with p-type impurity. In the in situ boron doping process, SiGe is epitaxially grown on the substrate while in situ doping the p-type impurity (boron). In the case where the non-doped SiGe is used for the SiGe layers 27, p-type diffusion regions 27A (defined by dashed line in FIG. 6) connecting the extension regions 21 and the source and drain regions are formed by ion implantation. Incidentally, in the case where the boron (B) doped SiGe is used for the SiGe layers 27, the p-type diffusion regions 27A are not specifically required.

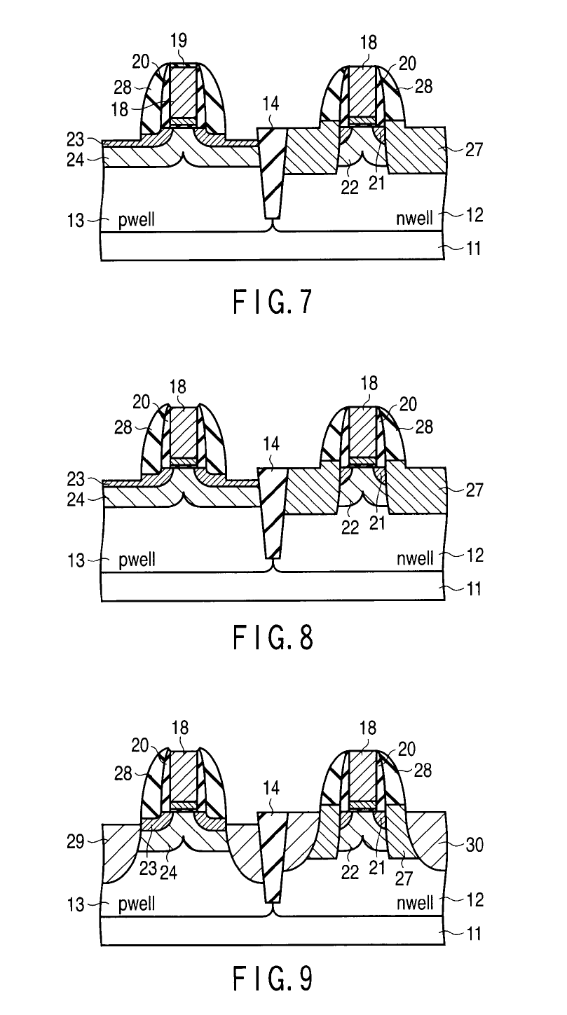

As shown in FIG. 7, a sidewall 28 for the source/drain region is formed on each side surface of the sidewalls 20. Each sidewall 28 is formed of, for example, a silicon oxide (SiO₂). The semiconductor substrate 11 and the SiGe layers 27 are etched at the time of processing the sidewalls. As long as the SiGe layers 27 are formed thicker correspondingly, however, the upper surfaces of the SiGe layers 27 exposed become substantially flush with the upper surface of the semiconductor substrate 11 directly under the laminated gate structure 18. Also, the hard mask 19 of the pMOSFET is removed by dry etching at the time of processing the sidewalls.

As shown in FIG. 8, the hard mask 19 of the nMOSFET is removed by dry etching. Incidentally, the hard mask 19 of the pMOSFET, if remaining, is removed by the same dry etching at the same time. As a result, the upper surfaces of the laminated gate structures 18 of the nMOSFET and the pMOSFET are exposed.

Then, as shown in FIG. 9, source and drain regions 29 are formed in the p-type well 13 by ion implantation using n-type impurity. The source and drain regions 29 become deeper than the halo regions 24. In the pMOSFET, on the other hand, source and drain regions 30 are formed in the n-type well 12 by ion implantation using p-type impurity. The source and drain regions 30 become deeper than the SiGe layers 27. At the same time, impurity is injected also into the polysilicon gate electrode 17 so that the polysilicon gate electrode 17 comes to have the conductivity. After that, the heat treatment is conducted to activate the ion implantation region. Incidentally, in the case where a sufficient boron concentration is secured in SiGe of the SiGe layers 27 formed by the in situ boron doping process, the SiGe layers 27 function as the source and drain regions 30, and therefore, the ion implantation to form the source and drain regions 30 is not required.

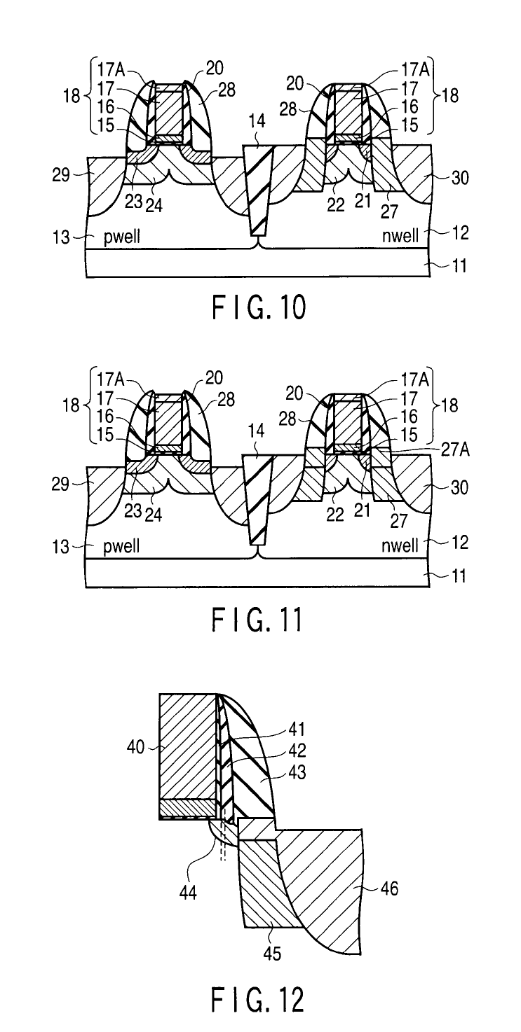

After that, as shown in FIG. 10, the upper part of the polysilicon gate electrode 17 is processed into a silicide. As a result, a silicide layer is formed on the polysilicon gate electrode 17. In this way, the semiconductor device according to the first embodiment is manufactured.

Incidentally, in the case where the non-doped SiGe is used as the SiGe layers 27, the p-type diffusion regions 27A are formed in the SiGe layers 27 as described above. As a result, the semiconductor device according to the first embodiment is produced in the form shown in FIG. 11. As shown in FIG. 11, the extension regions 21 and the source and drain regions 30 are electrically connected by the p-type diffusion regions 27A, and thus becomes operable as a MOSFET.

(Detailed MOSFET Structure)

First, the structure of the pMOSFET formed by the conventional method is explained. FIG. 12 is a sectional view showing a first example of the conventional pMOSFET structure. Three sidewalls (41, 42 and 43) are formed on the side surface of a laminated gate structure 40 including a metal gate. The sidewall 41 is required to form an extension region 44. The sidewall 42 is required to form a recess region for embedding an SiGe layer 45. The sidewall 43 is required to form a source-drain region 46.

The sidewall 41 is initially formed up to the dashed lines on the right side thereof in FIG. 12. By dry etching to process the sidewall 41, the upper surface of the extension region 44 is etched on the right side of the position indicated by the dashed lines. At the time of removing by wet etching the hard mask on the laminated gate structure 40, a part of the sidewall 41 is etched so that the side surface of the sidewall 41 is retreated toward the laminated gate structure 40. As a result, the side surface of the sidewall 41 is displaced from the edge of the depression of the extension region 44.

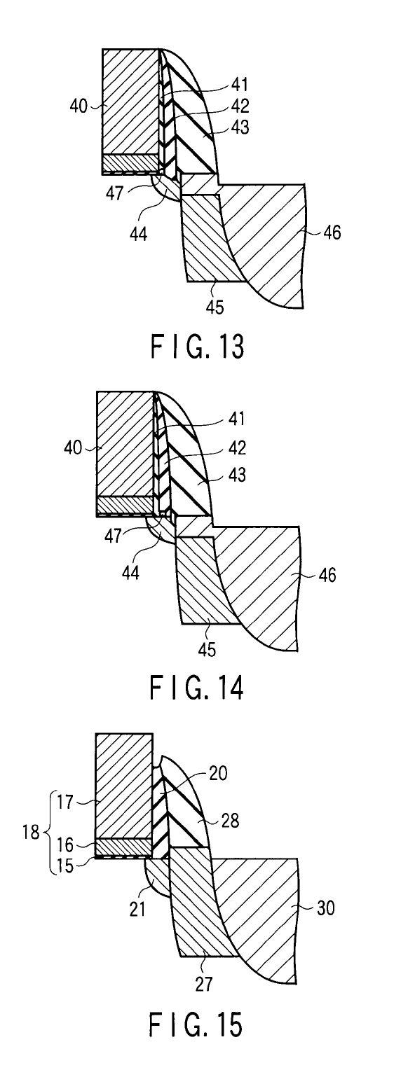

FIG. 13 is a sectional view showing a second example of the conventional pMOSFET structure. As shown in FIG. 13, at the time of removing the hard mask from the laminated gate structure 40 by wet etching, the lower part of the sidewall 41 is etched and formed with a horizontal depression. At the time of forming the sidewall 42 subsequently, an insulating material fails to intrude into the depression and a cavity 47 is formed in the lower part of the sidewall 41.

FIG. 14 is a sectional view showing a third example of the conventional pMOSFET structure. In FIG. 14, at the time of dry etching to process the sidewall 41, the lower part of the sidewall 41 is not etched, and a protrusion remains on the lower part of the sidewall 41. In the subsequent process of removing the hard mask on the laminated gate structure 40 by wet etching, the protrusion is etched, and a depression is formed horizontally in the lower part of the sidewall 41. At the subsequent time of forming the sidewall 42, a cavity 47 is formed in the lower part of the sidewall 41.

The pMOSFET according to the first embodiment is different from any of the structures shown in FIGS. 12 to 14. FIG. 15 is a sectional view showing by extracting the pMOSFET according to the first embodiment. In FIG. 15, the halo region 22 is not shown.

Two sidewalls 20, 28 are formed on the side surface of the laminated gate structure 18. The sidewall 20 is used in both the process of forming the extension region 21 (and the halo region 22) and the process of forming the recess region 26. The sidewall 28, on the other hand, is used to form the source/drain region 30.

As shown in FIG. 15, the side surface of the sidewall 20 is flush with the side surface of the extension region 21. So is the side surface of the sidewall 20 with the side surface of the SiGe layer 27. The upper surface of the SiGe layer 27 in contact with the sidewall 28 is higher than the upper surface of the channel region (or the upper surface of the extension region 21). In other words, the side surface of the upper part of the SiGe layer 27 is in contact with the side surface in the lower part of the sidewall 20.

The upper part of the sidewalls 20 and 28 is dry etched at the same time as the hard mask 19, and therefore, formed with a depression.

As described in detail above, according to the first embodiment, the sidewall 20 is formed on each side surface of the laminated gate structure 18 including the metal gate electrode 16, after which the halo regions 22 and the extension regions 21 are formed in the n-type well 12 using the sidewalls 20. Then, after forming the SiGe layers 27 in the n-type well 12, sidewalls 28 to form the source and drain regions are formed on the side surface of the sidewalls 20. After that, the hard mask 19 is removed by dry etching.

According to the first embodiment, therefore, the hard mask 19 can be removed without wet etching. As a result, the wet etching solution is kept out of contact with the sidewalls 20 protecting the metal gate electrode 16, and therefore, the metal is not exposed. Thus, the semiconductor device is prevented from being contaminated by the metal during the whole manufacturing process.

As to the nMOSFET, the sidewalls 20 to form the halo region and the extension region are formed in a single film formation step without the removal step. Therefore, the variation in the halo regions 24 and the extension regions 23 formed using the sidewalls 20 is reduced. As a result, the variation in the characteristics of the nMOSFET is reduced.

As to the pMOSFET, on the other hand, the SiGe layers 27 are formed after ion implantation for the halo regions 22 and the extension regions 21. As a result, the height of the SiGe layer 27 has no effect on the overlap amount between the extension region 21 and the laminated gate structure, and the characteristic variation of the pMOSFET can be suppressed.

Also, the ion implantation for the halo regions 22 is carried out for the semiconductor substrate 11, and the impurity is not implanted in the SiGe layers 27. Further, in the case where the in situ boron doping process is used, the ion implantation for the source and drain regions 30 is not carried out for the SiGe layers 27. As a result, the occurrence of a defect in the SiGe layers 27 which otherwise might be caused by the ion implantation is prevented, and therefore, the stress of SiGe is not released, thereby maintaining a high stress.

Also, since the recess regions 26 are formed after the halo regions 22, the halo regions 22 having the conductivity opposite to that of the source and drain regions 30 are not formed in the latter. Specifically, the p-type impurity region (source and drain regions 30) and the n-type impurity region (halo regions 22) do not coexist. As a result, the junction leakage current can be reduced at the bottoms of the source and drain regions 30.

Further, according to the manufacturing method according to the first embodiment, the height of the upper surface of the SiGe layer 27 can be increased above the upper surface of the semiconductor substrate 11 directly under the laminated gate structure 18. As a result, the volume of the SiGe layer 27 can be increased, with the result that the stress reduction of the SiGe layer 27 which otherwise might be caused by etching the SiGe layer 27 at the time of processing the sidewalls 28 can be suppressed.

Also, once the SiGe layers 27 are reduced in thickness by etching, the thicknesses of the source and drain regions 30 are also reduced, thereby increasing the resistance of the source and drain regions 30. This may undesirably degrade the performance of the MOSFET. According to this embodiment, however, the thicknesses of the source and drain regions 30 can be increased in keeping with the thickness increase of the SiGe formed. As a result, the resistance of the source and drain regions 30 can be reduced.

### Second Embodiment

According to the second embodiment, the semiconductor device is manufactured by a method different from the manufacturing method used in the first embodiment. An example of the method of manufacturing the semiconductor device (MOSFET) according to the second embodiment is explained with reference to the drawings.

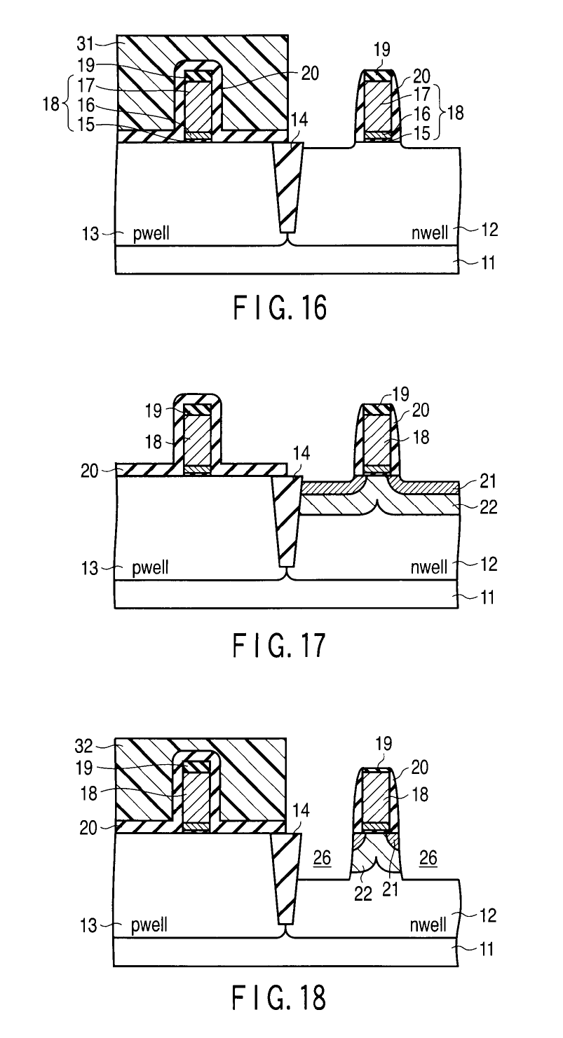

The manufacturing steps shown in FIG. 1 are identical with those of the first embodiment. After that, as shown in FIG. 16, an insulating film 20 of silicon nitride (SiN), for example, is deposited over the whole surface of the device. Then, a resist 31 covering the insulating film 20 on the nMOSFET side is formed by lithography. The insulating film 20 on the pMOSFET side is processed and a sidewall 20 is formed on each side surface of the laminated gate structure 18. The sidewall 20 is used for both the ion implantation to form the halo and extension regions and to protect the metal gate as a protective film. After that, the resist 31 is removed.

As shown in FIG. 17, ions are implanted in the n-type well 12 thereby to form the halo regions 22 and the extension regions 21 in the n-type well 12. Then, the heat treatment is conducted to activate the region in which impurity is injected. By this heat treatment, the amount of overlap between the extension region and the laminated gate structure 18 is determined. After that, in order to prevent the exposure of the gate edge due to the recess formation process for the pMOSFET, an SiN film may be additionally formed on the hard mask 19 and the sidewalls 20.

As shown in FIG. 18, a resist 32 covering the insulating film 20 on the nMOSFET side is formed by lithography. The semiconductor substrate 11 (specifically, the n-type well 12) is then etched thereby to form recess regions 26 in the n-type well 12. The recess regions 26 are at least deeper than the halo regions 22. The recess may be anisotropic in shape as shown in FIG. 18 or in the shape of Σ with the side surface of the recess region 26 depressed toward the semiconductor substrate 11.

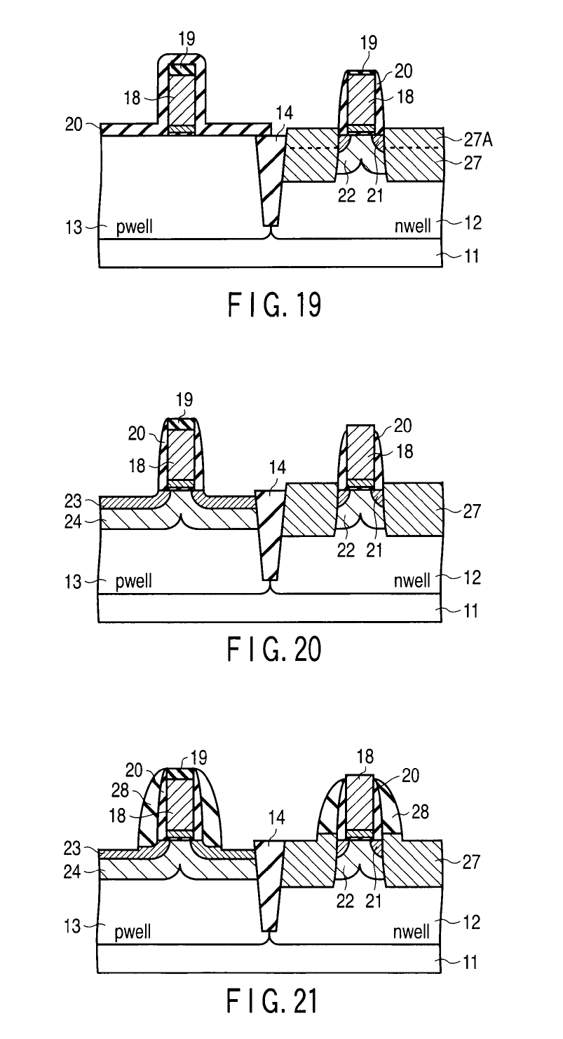

As shown in FIG. 19, the cleaning process (epitaxial pre-processing) is conducted to remove the natural oxide film from the surface of the semiconductor substrate 11, after which SiGe layers 27 are formed in the recess regions 26. In the process, each of the SiGe layers 27 is formed to have a thickness larger by the depth of the substrate part etched in processing the sidewall for the source/drain region. In FIG. 19, the upper surface of the SiGe layer 27 is higher than that of the semiconductor substrate 11 directly under the laminated gate structure 18.

The SiGe layers 27 may alternatively be formed using the in situ boron doping process or the non-doped SiGe not doped with p-type impurity. In the case where the non-doped SiGe is used for the SiGe layers 27, the p-type diffusion regions 27A (indicated by the dashed line in FIG. 19) connecting the extension regions 21 and the source and drain regions is formed by ion implantation. Incidentally, in the case where the boron (B) doped SiGe is used for the SiGe layers 27, the p-type diffusion regions 27A are not necessarily required.

Then, as shown in FIG. 20, the sidewalls 20 on the nMOSFET side are processed. In the process, the hard mask 19 on the pMOSFET side is partly removed or separated and the sidewall 20 is also partly etched by the dry etching process. After that, by ion implantation into the p-type well 13, the halo regions 24 and the extension regions 23 are formed in the p-type well 13. The heat treatment is conducted to activate the region in which impurities are injected. By this heat treatment, the amount by which the extension region and the laminated gate structure 18 are overlapped with each other is determined.

Then, as shown in FIG. 21, the sidewall 28 for the source/drain region are formed on each side surface of the sidewall 20. The sidewall 28 is formed of, for example, a silicon oxide (SiO₂). By the etching process executed at the time of processing the sidewall, the semiconductor substrate 11 and the SiGe layers 27 are etched. As long as the SiGe layer is formed thicker correspondingly, however, the upper surface of the SiGe layer 27 exposed remains substantially flush with the upper surface of the semiconductor substrate 11 directly under the laminated gate structure 18.

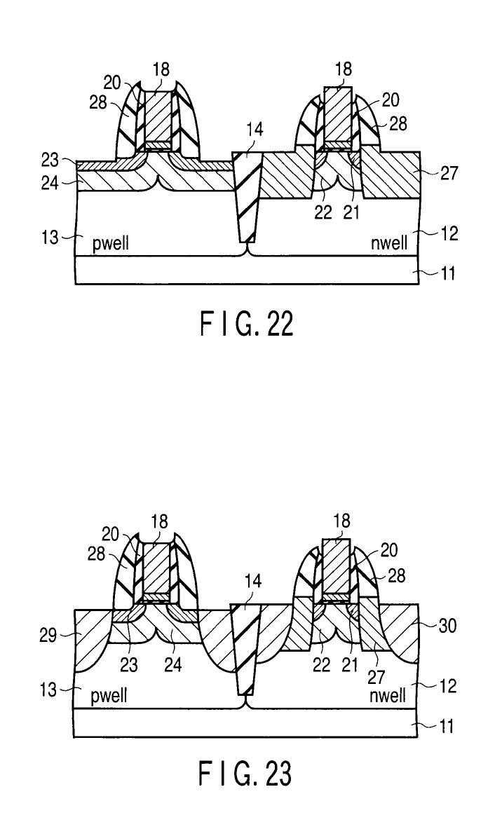

After that, as shown in FIG. 22, the hard mask 19 of the nMOSFET is removed by dry etching. Incidentally, the hard mask 19 of the pMOSFET, if left, is removed at the same time by this dry etching process. As a result, the upper surface of the laminated gate structure 18 of each of the nMOSFET and the pMOSFET is exposed.

Then, in the nMOSFET, as shown in FIG. 23, the source and drain regions 29 are formed in the p-type well 13 by ion implantation using n-type impurity. The source and drain regions 29 become deeper than the halo regions 24. In the pMOSFET, on the other hand, the source and drain regions 30 are formed in the n-type well 12 by ion implantation using p-type impurity. The source and drain regions 30 become deeper than the SiGe layers 27. In the process, impurity is injected also into the polysilicon gate electrode 17, so that the polysilicon gate electrode 17 comes to have the conductivity. After that, the heat treatment is conducted to activate the ion implantation region. Incidentally, in the case where a sufficient boron concentration is secured in SiGe of the SiGe layer formed by the in situ boron doping process, the SiGe layers 27 function as the source and drain regions 30, and therefore, the ion implantation to form the source and drain regions 30 is not required.

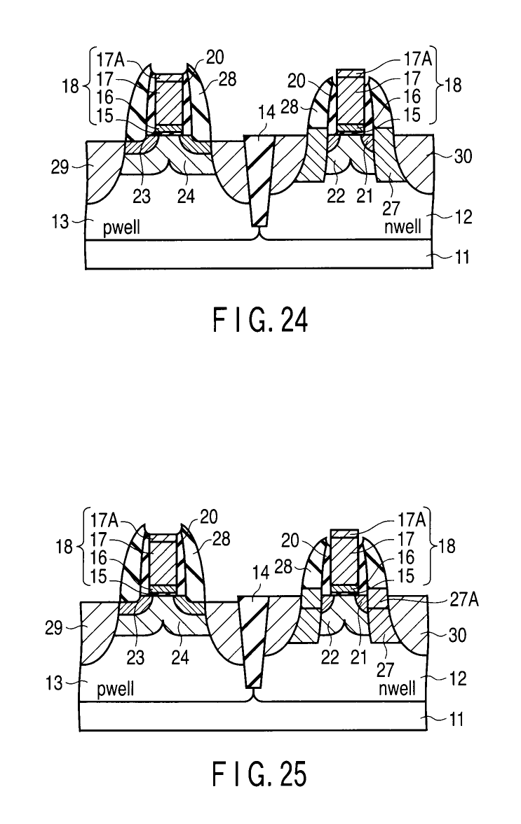

Then, as shown in FIG. 24, the upper part of the polysilicon gate electrode 17 is processed into a silicide. As a result, a silicide layer 17A is formed on the polysilicon gate electrode 17. In this way, the semiconductor device according to the second embodiment is manufactured.

In the case where the non-doped SiGe is used as the SiGe layers 27, as described above, the p-type diffusion regions 27A are formed in the SiGe layers 27. As a result, the semiconductor device according to the second embodiment takes the form as shown in FIG. 25. As shown in FIG. 25, the extension regions 21 and the source and drain regions 30 are electrically connected by the p-type diffusion regions 27A, and therefore, can operate as a MOSFET.

As described in detail above, according to the second embodiment, the sidewall 20 is formed on each side surface of the laminated gate structure 18 on the pMOSFET side while the laminated gate structure 18 on the nMOSFET side is covered by the insulating film 20, after which the halo regions 22 and the extension regions 21 are formed in the n-type well 12 using the sidewall 20 thereby to form the SiGe layer 27 in the n-type well 12. Then, after forming the sidewall 20 on each side surface of the laminated gate structure 18 on the nMOSFET side, the halo regions 24 and the extension regions 23 are formed in the p-type well 13 using the sidewall 20. After that, the hard mask 19 is removed by dry etching.

According to the second embodiment, therefore, the same advantage can be achieved as in the first embodiment. Also, during the epitaxial growth of the SiGe layers 27, the nMOSFET is covered by the insulating film 20. In the epitaxial growth process, therefore, the protective film covering the nMOSFET is not required to be formed. Also, the thermal budget to form the epitaxial film in the extension regions 23 of the nMOSFET can be reduced.

Incidentally, the difference in configuration between the pMOSFET formed in the conventional process and the pMOSFET shown in the second embodiment is the same as the difference described in the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, the method comprising:
depositing a laminate film comprising a material of a gate insulating film and a material of a metal gate electrode on a semiconductor substrate;
forming a mask layer on the laminate film;
processing the laminate film using the mask layer as a mask, and forming a gate structure comprising the gate insulating film and the metal gate electrode on the semiconductor substrate;
forming two first sidewalls of an insulating material on both side surfaces of the gate structure;
introducing impurity into the semiconductor substrate using the first sidewalls as a mask, and forming two extension regions of a first conductivity type and two halo regions of a second conductivity type deeper than the extension regions in the semiconductor substrate;
forming two recess regions on the semiconductor substrate by etching the semiconductor substrate using the first sidewalls as a mask;
forming SiGe layers in the recess regions;
forming two second sidewalls of an insulating material on side surfaces of the first sidewalls; and
dry etching the mask layer.

2. The method of claim 1, wherein upper surfaces of the SiGe layers are higher than an upper surface of the semiconductor substrate directly under the gate structure.

3. The method of claim 1, further comprising introducing impurity of the first conductivity type into the SiGe layer using the second sidewalls as a mask, and forming a source region and a drain region in the SiGe layers.

4. The method of claim 3, further comprising, after forming the SiGe layers, introducing impurity of the first conductivity type into the SiGe layers, and forming two diffusion regions electrically connecting the extension regions, the source region and the drain region in upper parts of the SiGe layers.

5. The method of claim 1, wherein the SiGe layers have the first conductivity type.

6. The method of claim 1, wherein the laminate film comprises a material of a polysilicon gate electrode stacked on the material of the metal gate electrode.

7. A method of manufacturing a semiconductor device, the method comprising:
preparing a substrate comprising an n-type first semiconductor region formed with a p-type MOSFET and a p-type second semiconductor region formed with an n-type MOSFET;
depositing a laminate film comprising a material of a gate insulating film and a material of a metal gate electrode on the substrate;
forming a mask layer on the laminate film;
processing the laminate film using the mask layer as a mask, and forming a first gate structure and a second gate structure each comprising the gate insulating film and the metal gate electrode on the first semiconductor region and the second semiconductor region, respectively;
covering the second gate structure and the second semiconductor region with an insulating film;
forming two first sidewalls of an insulating material on both side surfaces of the first gate structure;
introducing impurity into the first semiconductor region using the first sidewalls as a mask, and forming two first extension regions and two first halo regions deeper than the first extension regions in the first semiconductor region, the first extension regions being of p type, the first halo regions being of n type;
forming two recess regions in the first semiconductor region by etching the first semiconductor region using the first sidewalls as a mask;
forming SiGe layers in the recess regions;
processing the insulating film and forming two second sidewalls of an insulating material on both side surfaces of the second gate structure;
introducing impurity into the second semiconductor region using the second sidewalls as a mask, and forming two second extension regions and two second halo regions deeper than the second extension regions in the second semiconductor region, the second extension regions being of n type, the second halo regions being of p type;
forming two third sidewalls of an insulating material on side surfaces of the first sidewalls;
forming two fourth sidewalls of an insulating material on side surfaces of the second sidewalls; and
dry etching the mask layer.

8. The method of claim 7, wherein upper surfaces of the SiGe layers are higher than an upper surface of the first semiconductor region directly under the first gate structure.

9. The method of claim 7, further comprising:
introducing p-type impurity into the SiGe layers using the third sidewalls as a mask, and forming a first source region and a first drain region in the SiGe layers; and
introducing n-type impurity into the second semiconductor region using the fourth sidewalls as a mask, and forming a second source region and a second drain region in the second semiconductor region.

10. The method of claim 9, further comprising, after forming the SiGe layers, introducing p-type impurity into the SiGe layers, and forming two diffusion regions electrically connecting the first extension regions, the first source region and the first drain region in upper parts of the SiGe layers.

11. The method of claim 7, wherein the SiGe layers are of p type.

12. The method of claim 7, wherein the laminate film comprises a material of a polysilicon gate electrode stacked on the material of the metal gate electrode.

13. A semiconductor device comprising:
first and second SiGe layers provided in spaced relation with each other in a semiconductor substrate;
a gate structure provided on the semiconductor substrate between the first and second SiGe layers and comprising a gate insulating film and a metal gate electrode; and
first and second sidewalls of an insulating material provided on both side surfaces of the gate structure,
wherein a side surface of the first SiGe layer is flush with a side surface of the first sidewall, and
a side surface of the second SiGe layer is flush with a side surface of the second sidewall.

14. The device of claim 13, wherein an upper surface of each of the first and second SiGe layers is higher than an upper surface of the semiconductor substrate directly under the gate structure.

15. The device of claim 13, further comprising:
a third sidewall of an insulating material provided on the first SiGe layer and on the side surface of the first sidewall; and
a fourth sidewall of an insulating material provided on the second SiGe layer and on the side surface of the second sidewall.

16. The device of claim 13, further comprising:
Source and drain regions provided in the first and second SiGe layers, respectively; and
first and second extension regions provided in spaced relation with each other in the semiconductor substrate between the first and second SiGe layers, and electrically connected to the source and drain regions, respectively.

17. The device of claim 16, further comprising first and second halo regions provided in spaced relation with each other in the semiconductor substrate between the first and second SiGe layers at a position deeper than the extension regions, and having a conductivity type different from a conductivity type of the extension regions.

18. The device of claim 13, wherein the gate structure comprises a polysilicon gate electrode provided on the metal gate electrode.
